(19) United States
(12) Patent Application Publication
(10) Pub. No.: US 2005/0134336 A1
(43) Pub. Date: Jun. 23, 2005

(54) Adjustable-bias VCO

(76) Inventors: Jeremy Mark Goldblatt, Encinitas, CA (US); Hee Tae Ahn, San Diego, CA (US); Steven C. Ciccarelli, Ramona, CA (US)

Correspondence Address: Qualcomm Incorporated;Patents Department, 5775 Morehouse Drive, San Diego, CA, 92121-1714, US

(21) Appl. No.: 10/995,985

(22) Filed: Nov. 19, 2004

Related U.S. Application Data
(63) Continuation-in-part of application No. 10/690,655, filed on Oct. 21, 2003.
(60) Provisional application No. 60/423,218, filed on Oct. 31, 2002.
(60) Provisional application No. 60/471,227, filed on May 16, 2003.

(51) Int. Cl. H03L 7/06

(52) U.S. Cl. 327/156

(57) ABSTRACT

A dynamically programmable RF receiver includes an adjustable bias voltage-controlled oscillator (ABVCO) that operates in both low-interference and high-interference modes. The ABVCO uses a drive current to generate an output signal whose frequency varies based on a control voltage. When a jammer detector detects an interference signal, a state machine adjusts the ABVCO from the low-interference mode to the high-interference mode. Reciprocal mixing between the interference signal and phase noise in the output signal is reduced in the high-interference mode by increasing the drive current to reduce the phase noise. The ABVCO switches to the high-interference mode when a bias control circuit sends a bias control signal to the ABVCO, causing the ABVCO to generate the output signal using a greater amount of drive current. A programmable register contains a control value that determines the magnitude of the bias control signal and ultimately the magnitude of the drive current.

The present Application for Patent is a continuation in part of, and claims priority under 35 U.S.C. §120 from, pending nonprovisional U.S. patent application Ser. No. 10/690,655 entitled “Dynamically Programmable Receiver,” filed on Oct. 21, 2003, which claims priority to provisional application No. 60/423,218 entitled “Jammer Detection in a Direct Conversion Receiver” filed on Oct. 31, 2002 and provisional application No. 60/471,227 entitled “Dynamically Programmable Receiver” filed on May 16, 2003, and assigned to the assignee hereof, the subject matter of which is hereby expressly incorporated by reference herein. The present Application also claims priority to the following Patent Application: “LOW-POWER WIRELESS DIVERSITY RECEIVER WITH MULTIPLE RECEIVE PATHS” by Charles J. Persico, Kevin Gard, Gurkanwal Kamal Sahota, Shinichi Miyazaki and Steven C Ciccarelli, having Attorney Docket No. 030479, filed on Nov. 18, 2004, and expressly incorporated by reference herein.

### BACKGROUND

1. Field

The present disclosure relates generally to wireless communication devices and, more specifically, to a voltage controlled oscillator with an adjustable bias for a mobile station.

2. Background

Wireless networks and mobile stations (wireless handsets) conform to various technical standards for transmitting and receiving radio signals. For example, a wireless communication system may be designed to support one or more of the code division multiple access (CDMA) standards, such as (1) the “TIA/EIA-95-B Mobile Station-Base Station Compatibility Standard for Dual-Mode Wideband Spread Spectrum Cellular System” (the IS-95 standard promulgated by the Telecommunications Industry Association/Electronic Industry Association), (2) the related IS-98 standard for mobile station modems, (3) the standard offered by a consortium named “3^{rd} Generation Partnership Project” (3GPP) and embodied in a set of documents including Document Nos. 3G TS 25.211, 3G TS 25.212, 3G TS 25.213 and 3G TS 25.214 (the W-CDMA standard) and (4) the standard offered by a consortium named “3^{rd} Generation Partnership Project 2” (3GPP2) and embodied in the document “TR-45.5 Physical Layer Standard for cdma2000 Spread Spectrum Systems” (the IS-2000 standard). Other wireless communication systems may be designed to support a time division multiple access (TDMA) standard, such as the Global System for Mobile Communication (GSM) standard.

These wireless communication standards include minimum performance specifications for the circuitry of the mobile stations. Many wireless standards define narrow band systems that operate on an input radio frequency (RF) signal with a predetermined bandwidth and center frequency. The input RF signal typically includes other spurious signals located throughout the frequency spectrum. Non-linearity within the RF receiver causes intermodulation of the spurious signals and results in intermodulation products that may fall into the signal band. The wireless standards typically specify a spurious-free dynamic range that the RF receiver of the mobile station must exhibit. The spurious-free dynamic range is a frequency range wherein an input RF signal with a defined strength is not obscured despite the presence of an interference signal (a jammer) with a defined strength and a defined offset (e.g., 2 MHz) from the input RF signal. The RF receiver typically includes a local oscillator that emits out-of-band phase noise. The spurious-free dynamic range is limited by “reciprocal mixing” of the out-of-band phase noise and the interference signals. In order to comply with the wireless standard, the RF receiver must be designed in such a way that the defined jammer does not mix with the out-of-band phase noise of the local oscillator to such an extent that the input RF signal is obscured when the phase noise is translated into the band of the input RF signal.

In order to comply with the spurious-free dynamic ranges specified in the wireless standards, the local oscillators of RF receivers are designed to have reduced phase noise. As indicated in Leeson's phase-noise model, phase noise is inversely proportional to an oscillator's output power. Thus, by increasing the current that powers a local oscillator, the phase noise emitted by the local oscillator relative to the RF carrier signal is decreased. Relative phase noise decreases when the drive current to the active stages of the oscillator increases, causing an increase in the voltage swings in the resonant tank of the oscillator. Conversely, as signal swings are reduced by reducing drive current, the relative phase noise increases. Leeson's equation also indicates that phase noise is inversely proportional to the quality factor (Q) of an oscillator. Using more drive current to induce oscillation may also decrease phase noise by an additional amount by increasing the loaded Q of the oscillator.

An RF receiver design that reduces phase noise by increasing drive current to the oscillator, however, is especially undesirable in a portable mobile station powered by a battery. The increased current consumed by the local oscillator in order to decrease out-of-band phase noise results in shorter battery life for the mobile station. Being able to extend battery life is very valuable because a mobile station with a longer battery life is more attractive to consumers. Thus, a technique is sought whereby the RF receiver of a mobile station can comply with the spurious-free dynamic ranges specified by the various wireless standards and yet can reduce the high level of current that is supplied to the local oscillator in order to decrease out-of-band phase noise.

### SUMMARY

A dynamically programmable radio frequency (DPRF) receiver includes an adjustable bias voltage-controlled oscillator (ABVCO) that operates in a low-current, low-interference mode and in a high-current, high-interference mode. In one aspect, the ABVCO uses a drive current to generate an output signal whose frequency varies based on a control voltage. The DPRF receiver also includes a bias control circuit, a jammer detector, a state machine and a programmable register. When the jammer detector detects an interference signal, the state machine adjusts the ABVCO from the low-interference mode to the high-interference mode. Reciprocal mixing between the interference signal and phase noise in the output signal is reduced in the high-interference mode by increasing the drive current in order to reduce the phase noise in the output signal. The ABVCO switches to the high-interference mode in response to receiving a bias control signal from the bias control circuit, which causes the ABVCO to generate the output signal using a greater amount of drive current. The programmable register contains a control value that determines the magnitude of the bias control signal and ultimately the magnitude of the drive current. In another aspect, the bias control circuit, the jammer detector, the state machine and the programmable register communicate via a serial bus interface.

The frequency of the output signal varies based not only on the control voltage, but also on the magnitude of the drive current. When the control voltage initially remains constant and the magnitude of the drive current changes from a first magnitude to a second magnitude, the frequency of the output signal changes from a first frequency to a second frequency. In another aspect, the ABVCO is part of a phase-locked loop that adjusts the control voltage to return the frequency of the output signal to the first frequency within five milliseconds after the magnitude of the drive current changes from the first magnitude to the second magnitude.

In another aspect, once the state machine adjusts the ABVCO to the high-current, high-interference mode, the state machine holds the ABVCO in the high-interference mode for a predetermined stabilizing period, even if no additional interference signals are detected during the stabilizing period. By holding the ABVCO in the high-interference mode over the stabilizing period, the DPRF receiver is prevented from chattering between modes. After the predetermined stabilizing period has elapsed, and if no interference signal is detected, the state machine returns the ABVCO back to the low-current, low-interference mode.

In yet another aspect, the DPRF receiver receives an RF signal together with an interference signal. The jammer detector detects the interference signal, which indicates a high-interference condition. The programmable register is then programmed with a control value that corresponds to the high-interference condition. The control value is read from the programmable register, and the bias control circuit generates a bias control signal whose magnitude is based on the control value. In response to the bias control signal, the ABVCO is adjusted from the low-current, low-interference mode to the high-current, high-interference mode. The ABVCO then generates the output signal using a greater amount of current in the high-interference mode than in the low-interference mode. The output signal generated with the greater amount of current exhibits lower relative phase noise.

In another aspect, the ABVCO can be adjusted to operate in multiple interference modes. For example, the ABVCO may operate in a low-interference mode, a high-interference mode and a second high-interference mode. The programmable register is programmed with various control values, each of which corresponds to a different magnitude of the bias control signal. The ABVCO is adjusted to generate the output signal with various amounts of current based on the various magnitudes of the bias control signal.

Other embodiments and advantages are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 is schematic block diagram of an RF receiver that includes a local oscillator;

FIG. 2 is a more detailed block diagram of the local oscillator of FIG. 1 including an adjustable-bias voltage controlled oscillator;

FIG. 3 is a flowchart of steps for adjusting the bias voltage of the adjustable-bias voltage controlled oscillator of FIG. 2;

FIG. 4 is a more detailed block diagram of the adjustable-bias voltage controlled oscillator of FIG. 2;

FIG. 5 is a simplified circuit diagram of the adjustable-bias voltage controlled oscillator of FIG. 4;

FIG. 6 is a diagram of current waveforms illustrating the operation of the adjustable-bias voltage controlled oscillator of FIG. 5;

FIG. 7 is a diagram of voltage waveforms illustrating the operation of the adjustable-bias voltage controlled oscillator of FIG. 5;

FIG. 8 is a diagram of current waveforms illustrating the transient response of the adjustable-bias voltage controlled oscillator of FIG. 5;

FIG. 9 is a diagram of voltage waveforms illustrating the transient response of the adjustable-bias voltage controlled oscillator of FIG. 5; and

FIG. 10 is a waveform diagram illustrating the settling time of the local oscillator of FIG. 1 after a disturbance in drive current to the adjustable-bias voltage controlled oscillator of FIG. 2.

### DETAILED DESCRIPTION

Reference will now be made in detail to some embodiments of the invention, examples of which are illustrated in the accompanying drawings.

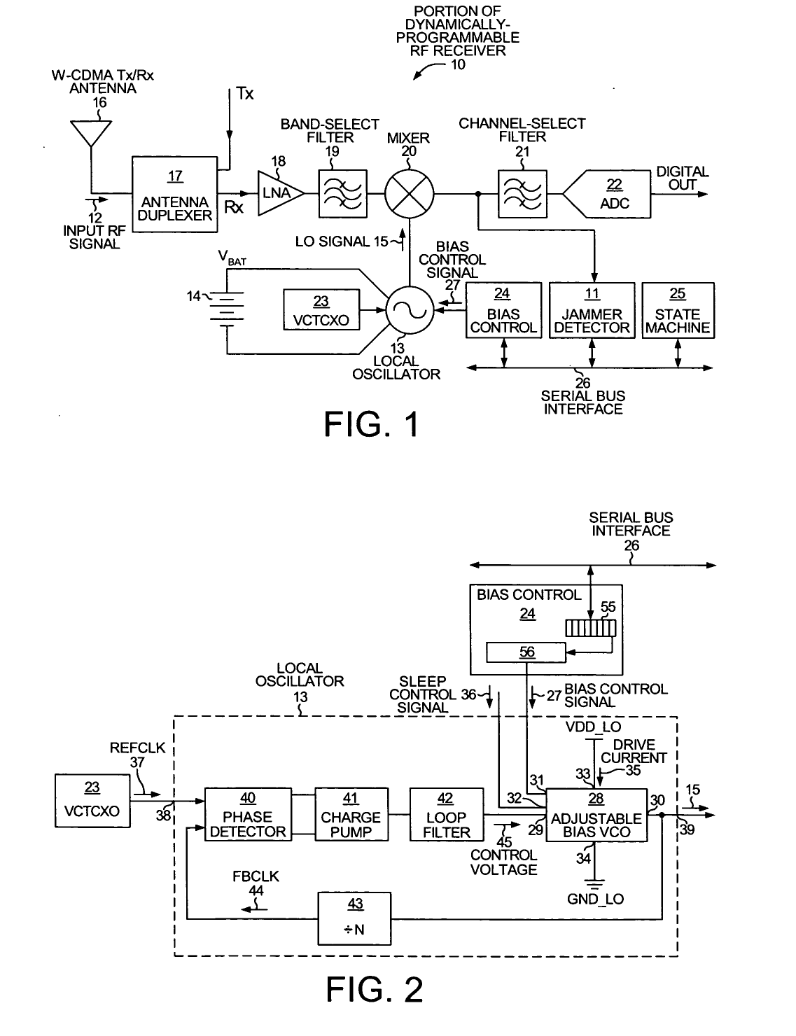

FIG. 1 shows a portion of a dynamically-programmable RF (DPRF) receiver 10 with a jammer detector 11 for detecting the presence of interference signals in the proximity of an input RF signal 12. DPRF receiver portion 10 includes a local oscillator 13 that uses a current supplied by a battery 14 to generate a local oscillator (LO) signal 15. DPRF receiver portion 10 is capable of adjusting the current downward if no interference signals are detected, which improves the receiver's standby time and prolongs the life of battery 14. Prolonging the life of battery 14 is especially beneficial when DPRF receiver portion 10 is part of a mobile station of a wireless handheld device, such as a cell phone or personal digital assistant (PDA). DPRF receiver portion 10 includes an antenna 16, an antenna duplexer 17, a low noise amplifier (LNA) 18, a band-select filter 19, a mixer 20, a channel-select filter 21 and an analog-to-digital converter (ADC) 22. LO signal 15 is the carrier signal for the receive path of the RF receiver. As part of the process of converting input RF signal 12 into a baseband signal for baseband processing, mixer 20 mixes LO signal 15 with the amplified and filtered radio frequency signal received onto antenna 16.

DPRF receiver portion 10 also includes a voltage-controlled, temperature-compensated crystal oscillator (VCTCXO) 23, a bias control circuit 24, a state machine 25 and a serial bus interface 26. DPRF receiver portion 10 is shown in FIG. 1 as part of a mobile station that complies with the W-CDMA standard, and antenna 16 is a W-CDMA transmit/receive antenna. According to the present disclosure, however, the disclosed local oscillator 13, bias control circuit 24, state machine 25 and a serial bus interface 26 may be used with any configuration of wireless device generally referred to herein as DPRF receiver portion 10, which may be a CDMA, TDMA, GSM or other device. In this example, DPRF receiver portion 10 converts input RF signal 12 into a baseband signal for baseband processing by a baseband processor that provides a CDMA demodulation function. One example of a baseband processor is a mobile station modem (MSM). In the embodiment of FIG. 1, DPRF receiver portion 10 is incorporated into an RF chip that is separate from the baseband processor. Although state machine 25 is shown as part of DPRF receiver portion 10 on the RF chip in the embodiment of FIG. 1, in other embodiments state machine 25 is not part of DPRF receiver portion 10. In another embodiment, for example, state machine 25 is part of the mobile station modem (MSM).

Bias control circuit 24, jammer detector 11 and state machine 25 communicate over serial bus interface 26. A reference oscillator, such as VCTCXO 23, generates a reference clock signal that is received by local oscillator 13 and is used to generate LO signal 15. Bias control circuit 24 adjusts the bias current of various circuit portions of the dynamically-programmable RF receiver, including DPRF receiver portion 10. Local oscillator 13 receives a bias control signal 27 from bias control circuit 24. By setting the current of bias control signal 27, bias control circuit 24 adjusts the current that powers local oscillator 13. When jammer detector 11 detects the presence of an interference signal, state machine 25 instructs bias control circuit 24 to adjust the power consumption level of local oscillator 13 based on the relative strength of the interference signal relative to the strength of input RF signal 12. The relative strengths of RF signal 12 relative to the interference signal is characterized as the carrier-to-noise ratio.

FIG. 2 shows local oscillator 13 in more detail. Local oscillator 13 is a phase-locked loop that includes an adjustable-bias voltage controlled oscillator (ABVCO) 28. ABVCO 28 has an input port 29, an output port 30, a bias control port 31, a sleep control port 32, a power-supply node 33 and a ground node 34. A drive current 35 that powers ABVCO 28 is received onto power-supply node 33. Bias control signal 27 is received onto bias control port 31. Drive current 35 can be adjusted such that the amount of current used by ABVCO 28 to generate LO signal 15 is less in a low-interference environment than in a high-interference environment. A sleep control signal 36 is received onto sleep control port 32. When sleep control signal 36 is asserted, ABVCO 28 is powered down and LO signal 15 is no longer generated.

Local oscillator 13 receives a reference clock signal (REFCLK) 37 from VCTCXO 23 onto an LO input port 38 and outputs LO signal 15 onto an LO output port 39. LO output port 39 is coupled to output port 30 of ABVCO 28. Local oscillator 13 includes a phase detector 40, a charge pump 41, a loop filter 42, ABVCO 28 and a frequency divider 43. Phase detector 40 compares the phase of reference clock signal 37 to the phase of a feedback signal (FBCLK) 44 and generates phase-error signals. Feedback signal 44 is a “divide-by-n” signal output by frequency divider 43. Frequency divider 43 divides the frequency of LO signal 15 output by ABVCO 28. When the phase of feedback signal 44 lags behind that of reference clock signal 37, phase detector 40 sends an accelerate control signal to charge pump 41. When the phase of feedback signal 44 leads that of reference clock signal 37, phase detector 40 sends a decelerate control signal to charge pump 41. Charge pump 41 drains charge from its output lead upon receiving an accelerate control signal and adds charge to its output lead upon receiving a decelerate control signal. Input port 29 of ABVCO 28 is coupled to the output lead of charge pump 41, and the charge drained and added by charge pump 41 constitutes a control voltage 45 received by ABVCO 28. Loop filter 42 is also coupled to the node that couples input port 29 of ABVCO 28 and the output lead of charge pump 41. As control voltage 45 increases, the frequency of LO signal 15 output by ABVCO 28 decreases.

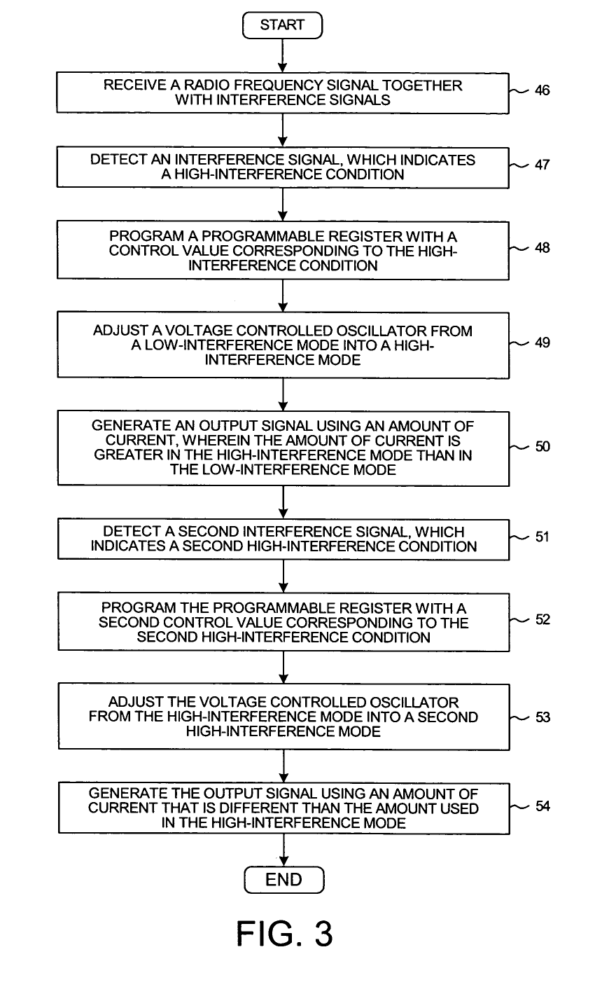

FIG. 3 is a flowchart showing steps by which the bias current of ABVCO 28 can be adjusted such that the amount of drive current 35 used by ABVCO 28 to generate LO signal 15 is less in a low-interference condition than in a high-interference condition. The operation of individual elements of DPRF receiver portion 10, as shown in FIG. 1 and FIG. 2, is explained in detail in connection with the steps listed in FIG. 3. In a step 46, DPRF receiver portion 10 receives input RF signal 12 together with an interference signal on antenna 16. In this example, RF signal 12 and the interference signal have frequencies that differ by less than two megahertz.

In a step 47, jammer detector 11 detects the interference signal by determining that the interference signal falls within a predetermined frequency offset from RF signal 12 (in this case within two megahertz) and that the interference signal has at least a predetermined strength. Upon detecting an interference signal with a predetermined amplitude, jammer detector 11 generates an interrupt to the microprocessor of the mobile station modem. The microprocessor is interrupted and a jammer detect signal is asserted. The jammer detect signal causes the microprocessor to read an event register. In this embodiment, the event register is located on the RF receiver. State machine 25 adjusts individual elements of DPRF receiver portion 10 depending on the event that has occurred. In this example, the interference signal that was detected is of a particular type that causes state machine 25 to adjust ABVCO 28 from a low-interference condition to a high-interference condition.

In the embodiment of FIG. 1, where state machine 25 is part of DPRF receiver portion 10 on the RF chip, it may not be necessary to generate an interrupt signal to the microprocessor if state machine 25 can operate autonomously. In embodiments where state machine 25 is part of the mobile station modem (MSM), however, interrupt signals are generated when interference signals are detected.

In a step 48, a programmable register is programmed with a control value that corresponds to the high-interference condition. The control value is a digital number that determines the current magnitude of bias control signal 27. State machine 25 causes the control value to be written to a VCO control register 55 (the programmable register) by sending a serial bus message over serial bus interface 26. In the embodiment of FIG. 2, VCO control register 55 is part of bias control circuit 24. In other embodiments, VCO control register 55 can be part of ABVCO 28 or of the mobile station modem. A high-interference control value is loaded into VCO control register 55 and replaces the low-interference control value that was previously stored there. A variable current generator 56 generates bias control signal 27 by converting the digital control value into a signal having a corresponding magnitude of current.

In a step 49, ABVCO 28 is adjusted from a low-interference mode to a high-interference mode when the current magnitude of bias control signal 27 received on bias control port 31 increases.

In a step 50, ABVCO 28 generates LO signal 15 in the high-interference mode using a greater amount of drive current 35 than used to generate LO signal 15 in the low-interference mode. When LO signal 15 is generated using a greater amount of drive current 35, the voltage swings in the oscillator tanks of ABVCO 28 increase, and the relative phase noise in LO signal 15 decreases. As less out-of-band phase noise is emitted by local oscillator 13, reciprocal mixing is reduced.

Using more current to induce oscillation in an oscillator not only reduces relative phase noise by increasing oscillator output power, but also may reduce relative phase noise by increasing the loaded quality factor (Q) of the oscillator. For example, passing more current through a transistor coupled to a resonant LC tank may change the impedance of the transistor and thereby increase the loaded Q of the oscillator. The Q of an oscillator is the ratio of the ability of the oscillator to store energy to the sum total of all energy losses within the oscillator. As more current is used to induce oscillation in local oscillator 13, the loaded Q of local oscillator 13 may increase. An oscillator with a higher Q emits a narrower bandwidth of frequencies than does an oscillator with a lower Q. According to Leeson's equation, phase noise decreases as Q increases. Thus, a second-order effect of increasing the drive current to local oscillator 13 may be to increase the loaded Q such that local oscillator 13 emits less out-of-band phase noise in the form of signals at frequencies away from the desired local oscillator frequency.

Once state machine 25 has caused ABVCO 28 to switch to the high-interference, high-current mode, state machine 25 holds ABVCO 28 in the high-interference mode for a predetermined stabilizing period, regardless of whether further interference signals are detected within the stabilizing period. The stabilizing period is measured by a timer within state machine 25. By holding ABVCO 28 in the high-interference mode over the stabilizing period, the RF receiver is prevented from chattering between the high and low interference modes. After the predetermined stabilizing period has elapsed, and if no interference signal is detected, state machine 25 causes ABVCO 28 to switch back to the low-current, low-interference mode.

During normal operation of DPRF receiver portion 10 within a wireless handheld device, interference signals will seldom be detected. Therefore, most of the time, the robust performance of the high-interference mode will not be required. In the low-interference mode when jammers are absent, battery life can be extended by generating LO signal 15 using a smaller amount of current than in the high-interference mode. Although LO signal 15 will have more phase noise in the low-interference mode, no significant reciprocal mixing will occur because of the absence of jammers. DPRF receiver portion 10 will nevertheless comply with the spurious-free dynamic range requirements specified by the wireless standards because ABVCO 28 will generate LO signal 15 using a larger amount of current as soon as an interference signal is detected. Reciprocal mixing between an interference signal and phase noise is kept within the tolerances specified by the wireless standards when phase noise is reduced by generating LO signal 15 with more current in the high-interference mode. Thus, DPRF receiver portion 10 with ABVCO 28 is a significant improvement over RF receiver designs that burn current as if a worst-case environment is constantly present when in fact the RF receiver experiences a benign environment most of the time.

In a step 51, jammer detector 11 detects a second interference signal. The second interference signal falls within a different frequency offset from RF signal 12 (for example, one megahertz) and falls within a different strength threshold (for example, double the strength of the first interference signal). Detecting the second interference signal is recorded as a different type of event than detecting the first interference signal. In this example, the second interference signal is identified as a second jammer type and causes state machine 25 to adjust ABVCO 28 from the high-interference condition to a second high-interference condition.

In a step 52, VCO control register 55 is programmed with a second control value that corresponds to the second high-interference condition. The second high-interference control value is loaded into VCO control register 55 and replaces the high-interference control value that was previously stored there. Variable current generator 56 generates bias control signal 27 by converting the second control value into a signal having a corresponding magnitude of current.

In a step 53, ABVCO 28 is adjusted from the high-interference mode to the second high-interference mode when the current magnitude of bias control signal 27 received on bias control port 31 increase to a third level.

In a step 54, ABVCO 28 generates LO signal 15 in the second high-interference mode using an even greater amount of drive current 35 than used to generate LO signal 15 in the high-interference mode. When LO signal 15 is generated using the even greater amount of drive current 35, even less out-of-band phase noise is emitted by local oscillator 13 than in the high-interference mode. Thus, ABVCO 28 can be adjusted to generate LO signal 15 having more than two levels of relative phase noise by using more than two magnitudes of current. By adjusting ABVCO 28 to operate at multiple bias current levels, ABVCO 28 can comply with the spurious-free dynamic range requirements specified by various wireless standards. Various control values are used depending on whether DPRF receiver portion 10 is being used to receive and transmit signals using a CDMA, TDMA or other wireless standard.

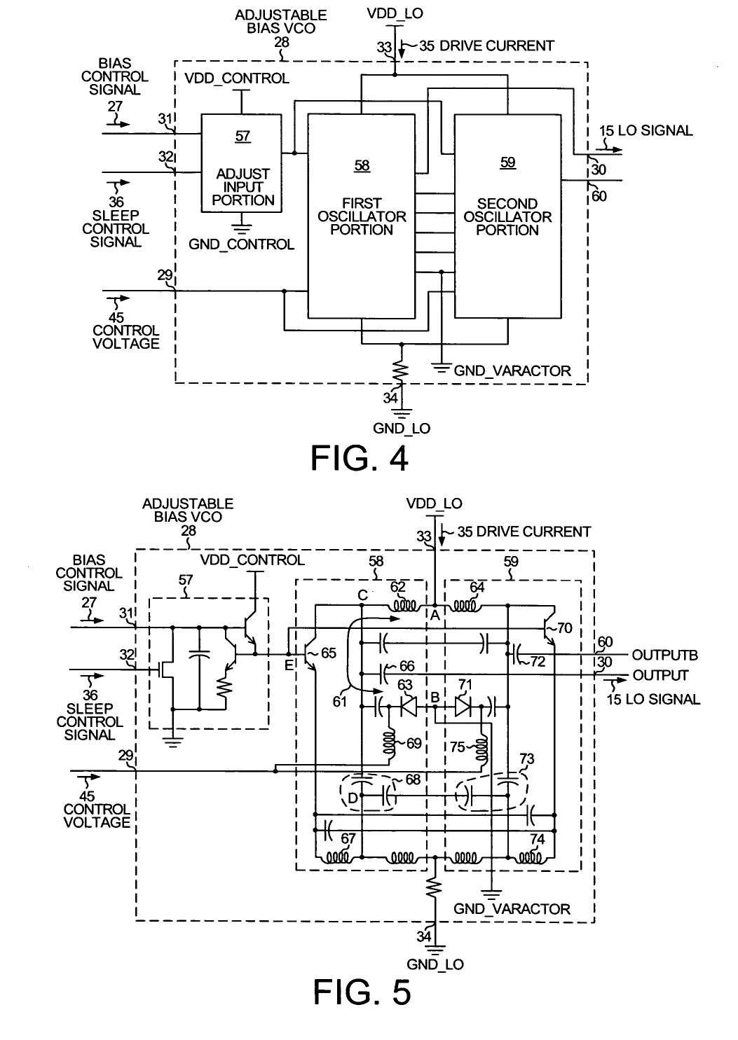

FIG. 4 shows ABVCO 28 in more detail. ABVCO 28 includes an input stage 57, a first oscillator 58 and a second oscillator 59. Input stage 57 receives bias control signal 27 and sleep control signal 36. Control voltage 45 is received by both first oscillator 58 and second oscillator 59. First oscillator 58 and second oscillator 59 are configured in a differential topology. First oscillator 58 outputs LO signal 15 onto output port 30. Second oscillator 59 outputs a complement of LO signal 15 onto an output port 60. LO signal 15 together with the complement of LO signal 15 constitute a differential signal. First oscillator 58 and second oscillator 59 can employ any type of oscillator topology. Although in this example, each of first oscillator 58 and second oscillator 59 is a cross-coupled, LC oscillator with an resonant LC tank coupled to a bipolar transistor, other oscillator types may also be used, for example, oscillators employing CMOS transistors or ring oscillators that employ an odd number of inverters in a ring. In embodiments with cross-coupled, LC oscillators, first oscillator 58 and second oscillator 59 may be Colpitts oscillators, which implement passive impedance transformation with capacitive dividers, Hartley oscillators, which implement passive impedance transformation with inductive dividers, Clapp oscillators or other types of cross-coupled, LC oscillators.

FIG. 5 is a schematic diagram showing one embodiment of ABVCO 28 in yet more detail. In the oscillator topology of this embodiment, each of first oscillator 58 and second oscillator 59 is a Colpitts oscillator with an LC tank that is coupled to the emitter of a bipolar transistor. Drive current 35 is supplied to the bipolar transistor of each of first oscillator 58 and second oscillator 59 through a node A. An LC tank 61 of first oscillator 58 includes an inductor 62 and a reverse-biased diode (a “varactor”) 63, in which the anode of the varactor is coupled through a node B to ground (GND_VARACTOR). In this embodiment, node A is coupled to inductor 62 of first oscillator 58 and to an inductor 64 of second oscillator 59. In other embodiments, however, inductor 62 and inductor 64 are implemented by tapping a single inductor spiral in the middle. Each of first oscillator 58 and second oscillator 59 exhibits a quality factor (Q). The Q of first oscillator 58 can be describes as the desired resonance frequency of the output signal of first oscillator 58 divided by the two-sided, −3 dB bandwidth of the actual output spectrum. The Q of first oscillator 58 is also an indication of how much of the energy in LC tank 61 is lost as the energy is transferred from varactor 63 to inductor 62 and vice versa.

First oscillator 58 includes a bipolar transistor 65, whose collector is coupled through a node C to inductor 62. Output port 30 of ABVCO 28 is coupled to node C through a capacitor 66. The emitter of bipolar transistor 65 is coupled through an inductor 67 at a node D to a capacitive divider 68. Input port 29 of ABVCO 28 is coupled through an inductor 69 to the cathode of varactor 63. Input stage 57 receives bias control signal 27 and sleep control signal 36 and supplies an output signal onto a node E that is coupled to the gate of bipolar transistor 65 as well as to the gate of a bipolar transistor 70 of second oscillator 59.

Second oscillator 59 is configured analogously to first oscillator 58, but outputs onto output port 60 a signal that is complementary to LO signal 15. Second oscillator 59 includes inductor 64, bipolar transistor 70, a varactor 71, a capacitor 72, a capacitive divider 73 and additional inductors 74 and 75.

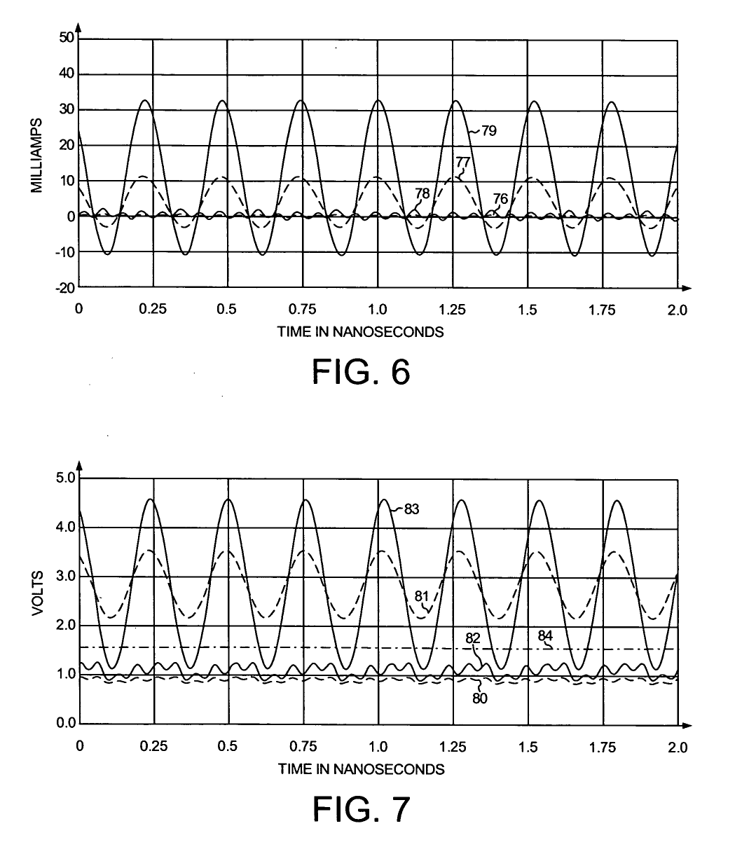

FIG. 6 is a waveform diagram illustrating the operation of ABVCO 28 in a low-interference mode and in a high-interference mode. FIG. 6 shows how a current waveform on node C responds to a current waveform on node E in both modes. A dashed curve 76 shows the small amount of current in milliamps flowing through node E in a low-interference mode. A dashed curve 77 shows the corresponding current at node C. Dashed curve 77 illustrates that an average of about five milliamps of current is consumed by first oscillator 58 as an oscillating signal is generated in LC tank 61 in the low-interference mode. When a high-interference control value is loaded into VCO control register 55 causing variable current generator 56 to generate bias control signal 27 with a greater magnitude of current, the bias current flowing through node E at the gate of bipolar transistor 65 also increases. A solid curve 78 shows the bias current flowing through node E after bias control signal 27 has been adjusted for the high-interference mode. When the bias current on node E increases to the level of solid curve 78, the current at node C driving LC tank 61 increases to an average of about ten milliamps, as illustrated by a solid curve 79. The current waveforms of the current driving the LC tank of second oscillator 59 (not shown) are of equal amplitude to curves 77 and 79, but are offset by 180 degrees.

FIG. 7 shows the voltage waveforms that correspond to the current waveforms of FIG. 6. A dashed curve 80 shows that the average voltage on node E in a low-interference mode is about 0.9 volts. A dashed curve 81 shows the corresponding voltage at node C. When a high-interference control value is loaded into VCO control register 55 causing the bias current at node E to increase, the voltage at the gate of bipolar transistor 65 also increases. A solid curve 82 shows the bias voltage at node E after bias control signal 27 has been adjusted for the high-interference mode. The average voltage at node E in the high-interference mode is about 1.2 volts. When the bias voltage on node E increases to the level of solid curve 82, the voltage at node C of LC tank 61 increases as illustrated by a solid curve 83. A dotted-dashed line 84 shows the voltage on node A, which remains approximately constant at 1.6 volts in both the low-interference mode and in the high-interference mode.

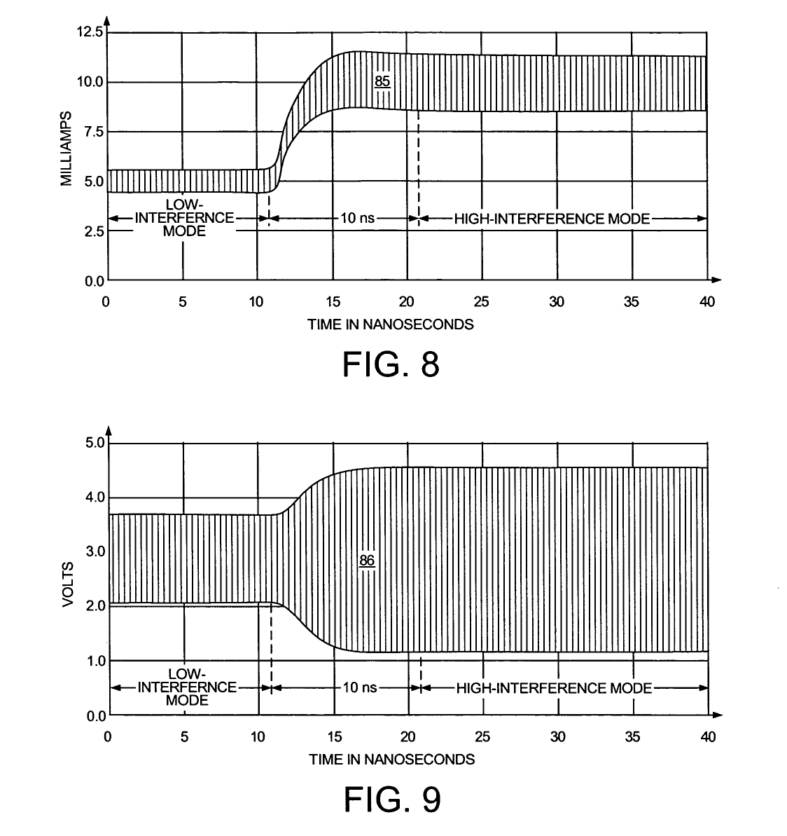

FIG. 8 is a diagram of current waveforms that illustrates the transient response of ABVCO 28 when an interference signal is detected. An envelope 85 of current waveforms shows the manner in which the current at node C driving LC tank 61 increases in response to a change in bias control signal 27. Within about five nanoseconds of an adjustment in bias control signal 27 from the low-interference mode to the high-interference mode, the amount of current flowing through node C changes from an average of about five milliamps to more than ten milliamps. After about ten nanoseconds from the adjustment into the high-interference mode, the current at node C stabilizes at an average of about ten milliamps. Before the transition from low-interference mode to high-interference mode, envelope 85 represents the maximum and minimum current amplitudes of waveforms similar to current waveform 77. After the transition, envelope 85 represents the maximum and minimum current amplitudes of waveforms similar to current waveform 79.

FIG. 9 shows an envelope 86 of voltage waveforms that illustrate the transition from the low-interference mode to the high-interference mode. Before the transition, envelope 86 represents the maximum and minimum voltage amplitudes of waveforms similar to voltage waveform 81. After the transition, envelope 85 represents the maximum and minimum voltage amplitudes of waveforms similar to voltage waveform 83. FIG. 8 and FIG. 9 illustrate the transition of ABVCO 28 from the low-interference mode to the high-interference mode. The transition of ABVCO 28 back to the low-current, low-interference mode occurs in an analogous manner, whereby the current at node C also stabilizes within about ten nanoseconds at the low-current level.

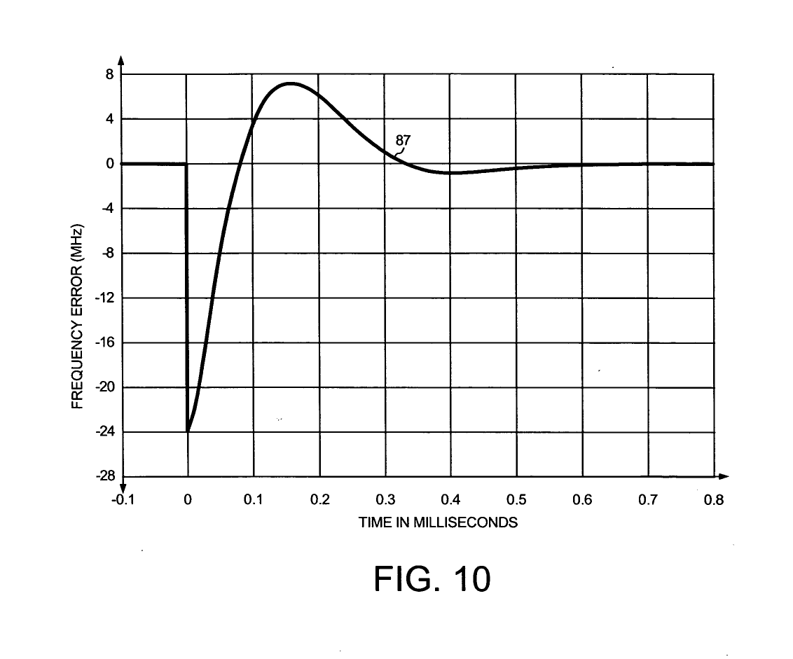

FIG. 10 shows the settling time of local oscillator 13, which is a PLL, after a disturbance in drive current 35 to ABVCO 28. Curve 87 shows the frequency error in megahertz of LO signal 15 following a transition from the low-interference mode to the high-interference mode. At time zero, bias control signal 27 adjusts the bias current at node E, thereby increasing drive current 35. As shown in FIG. 8, the transition of drive current 35 from an average of about five milliamps in the low-interference mode to an average of about ten milliamps in the high-interference mode occurs in about ten nanoseconds. In this example, the sudden increase in drive current 35 causes ABVCO 28 to output LO signal 15 with a frequency that is about twenty-four megahertz slower than before the transition. For example, where LO signal 15 has a frequency of about 4.0 GHz before the transition, LO signal 15 has a frequency of about 3.976 GHz about ten nanoseconds after the transition. Local oscillator 13 is a phase-locked loop and adjusts control voltage 45 over subsequent loop passes until the frequency of LO signal 15 returns to about 4.0 GHz. Local oscillator 13 preferably returns the frequency of LO signal 15 to its pre-disturbance frequency within about five milliseconds. In this example, LO signal 15 settles back to the pre-disturbance frequency within less than one millisecond. In fact, LO signal 15 has substantially settled back to the pre-disturbance frequency within about 500 microseconds. Nevertheless, in this example, the speed at which the phase-locked loop returns the frequency of LO signal 15 to the pre-disturbance frequency (the “PLL settling time”) is orders of magnitude slower than the speed at which drive current 35 transitions between a low-current, low-interference mode and a high-current, high-interference mode.

Different wireless standards may specify different maximum recovery times following a disturbance. For example, some TDMA wireless standards may require shorter recovery times than are common form CDMA wireless standards. In order to reduce the recovery time following a transition to a different bias voltage setting for a TDMA application, for example, the magnitude of the difference in current between a low-current, low-interference mode to a high-current, high-interference mode can be reduced. The recovery time can also be reduced by changing the loop bandwidth or the loop gain of local oscillator 13 such that the settling time of the PLL is reduced.

The recovery time can also be eliminated by gradually changing the drive current 35 during the transition between modes. In another embodiment, state machine 25 and bias control circuit 24 cause drive current 35 to change gradually upon a transition from one mode to another. The gradual change in drive current 35 has a duration of more than half the PLL settling time. Because the change in drive current 35 takes longer than half the PLL settling time, local oscillator 13 maintains a frequency lock with reference clock signal 37 from VCTCXO 23. In this embodiment, the transition between modes occurs more slowly but does not result in a time period during which the frequency of LO signal 15 deviates from the frequency of reference clock signal 37.

Although the present invention has been described in connection with certain specific embodiments for instructional purposes, the present invention is not limited thereto. A method is disclosed for controlling the drive current of a voltage controlled oscillator that is implemented on various circuit portions of a dynamically-programmable RF receiver by sending messages and processor instructions over a serial bus interface. Thus, the drive current is adjusted using a combination of both hardware and software. The method may also be practiced, however, by using hardware only or software only. In one embodiment, the ABVCO is adjusted to generate the output signal using various amounts of drive current based on the current of the bias control signal. In other embodiments, the voltage of the bias control signal determines the amount of drive current used to generate the output signal.

The ABVCO described above can be used to provide the local oscillator signal in the RF front-end stage or intermediate frequency (IF) stage of receivers that output downconverted baseband signals for subsequent digital signal processing. The ABVCO can be used in both heterodyne and homodyne, i.e., zero intermediate frequency (ZIF), receiver architectures. In this context, the ABVCO reduces relative phase noise by increasing drive current. In addition to reducing phase noise, the ABVCO can also be used to mitigate aperture jitter in the digital domain. For example, the ABVCO may reduce aperture jitter caused by integrated phase noise when the ABVCO is used to generate a clock signal for an analog-to-digital converter that directly digitizes an RF input signal from an antenna.

Although the ABVCO is described above as part of a local oscillator that is a phase-locked loop, the ABVCO can be used without a phase-locked loop. In one application, for example, the frequency of the output signal changes when the drive current of the ABVCO is adjusted, and the control voltage of the ABVCO is not subsequently adjusted to return the frequency of the output signal to its previous frequency.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Accordingly, the present invention is not intended to be limited to the embodiments shown herein but is to be accorded the widest scope consistent with the principles and novel features disclosed herein.

1. A circuit comprising:
an input port, wherein a control voltage is present on the input port;
an output port, wherein an output signal having a frequency is present on the output port;
a power-supply node that receives an amount of current; and
a bias control port, wherein a bias control signal is present on the bias control port, wherein the frequency of the output signal varies based on the control voltage, and wherein the amount of current varies based on the bias control signal.

2. The circuit of claim 1, wherein the circuit is part of a radio frequency receiver.

3. The circuit of claim 1, wherein the output signal is a clock signal for an analog-to-digital converter, and wherein the analog-to-digital converter directly digitizes a radio frequency input signal from an antenna.

4. The circuit of claim 1, wherein the circuit generates the output signal using the current.

5. The circuit of claim 4, wherein the output signal exhibits phase noise, and wherein the phase noise decreases as the amount of current increases.

6. The circuit of claim 1, further comprising:
a programmable register containing a control value, wherein the bias control signal has a magnitude, and wherein the magnitude of the bias control signal is based on the control value.

7. A circuit comprising:
a voltage controlled oscillator that uses a current to generate an output signal having a frequency, wherein the current has a magnitude; and
a programmable register containing a control value, wherein the magnitude of the current is based on the control value.

8. The circuit of claim 7, wherein the output signal exhibits phase noise, and wherein the phase noise decreases as the magnitude of the current increases.

9. The circuit of claim 7, wherein the programmable register is part of a radio frequency receiver.

10. The circuit of claim 7, wherein the magnitude of the current used by the voltage controlled oscillator to generate the output signal increases when the programmable register is programmed for a low carrier-to-noise ratio condition.

11. The circuit of claim 7, further comprising:
a jammer detector that detects an interference signal, wherein the programmable register is programmed with a first value when the jammer detector detects the interference signal, and wherein the magnitude of the current increases as a result of the programmable register being programmed with the first value.

12. The circuit of claim 11, wherein the programmable register is programmed with a second value upon the elapse of a predetermined length of time during which the jammer detector has not detected the interference signal, and wherein the magnitude of the current decreases as a result of the programmable register being programmed with the second value.

13. A circuit comprising:
an output port, wherein an output signal having a frequency is output onto the output port;
a control voltage port, wherein a control voltage is present on the control voltage port, wherein the frequency of the output signal varies based on the control voltage; and
a bias control port, wherein a bias control signal is received onto the bias control port, wherein the bias control signal has a magnitude, wherein the frequency of the output signal varies based on the magnitude of the bias control signal, wherein the frequency of the output signal changes from a first frequency to a second frequency when the control voltage initially remains constant and the magnitude of the bias control signal changes from a first magnitude to a second magnitude, and wherein the frequency of the output signal returns to the first frequency within five millisecond after the magnitude of the bias control signal changes from the first magnitude to the second magnitude.

14. The circuit of claim 13, wherein the circuit is a phase-locked loop.

15. The circuit of claim 13, wherein the circuit generates the output signal using an amount of current that varies based on the magnitude of the bias control signal.

16. The circuit of claim 13, wherein the circuit is part of a radio frequency receiver.

17. A method comprising:
detecting an interference signal indicative of a high-interference condition, wherein a low-interference condition exists during an absence of the interference signal; and
adjusting a voltage controlled oscillator from a low-interference mode to a high-interference mode, wherein the voltage controlled oscillator generates an output signal using an amount of current, wherein the amount of current used to generate the output signal is less in the low-interference mode than in the high-interference mode, and wherein the output signal exhibits greater phase noise in the low-interference condition than in the high-interference condition.

18. The method of claim 17, further comprising:
programming a programmable register with a control value corresponding to the high-interference condition, wherein the amount of current used to generate the output signal is based on the control value.

19. The method of claim 17, wherein the adjusting the voltage controlled oscillator involves reading a control value from a programmable register.

20. The method of claim 17, further comprising:
receiving a radio frequency signal, wherein the radio frequency signal and the interference signal have frequencies that differ by less than two megahertz.

21. The method of claim 17, wherein the adjusting the voltage controlled oscillator from the low-interference mode to the high-interference mode causes a abrupt increase in the amount of current used to generate the output signal, wherein the output signal has a frequency that changes from a first frequency to a second frequency upon the abrupt increase in the amount of current, wherein the frequency of the output signal returns to the first frequency within a PLL settling time, and wherein the abrupt increase occurs within less than one percent of the PLL settling time.

22. The method of claim 17, wherein the adjusting the voltage controlled oscillator from the low-interference mode to the high-interference mode causes a gradual increase in the amount of current used to generate the output signal, and wherein the output signal has a frequency that remains substantially unchanged during the gradual increase in the amount of current.

23. The method of claim 22, wherein the gradual increase in the amount of current has a duration of more than five nanoseconds.

24. The method of claim 17, further comprising:
detecting a second interference signal indicative of a second high-interference condition; and
adjusting the voltage controlled oscillator to a second high-interference mode, wherein the amount of current used to generate the output signal in the second high-interference mode is different than in the high-interference mode.

25. A circuit comprising:
an antenna that in a first condition receives a first signal and an interference signal and in a second condition receives the first signal without the interference signal;
an oscillator that generates an oscillating signal using a drive current; and
means for configuring the oscillator to generate the oscillating signal such that the drive current is smaller in the second condition than in the first condition.

26. The circuit of claim 25, wherein the oscillating signal exhibits phase noise, and wherein the oscillating signal exhibits more phase noise when the drive current is smaller in the second condition than when the drive current is larger in the first condition.

27. The circuit of claim 25, wherein the circuit is part of a radio frequency receiver.
